(19) United States
(12) Patent Application Publication
(10) Pub. No.: US 2013/0120030 A1
(43) Pub. Date: May 16, 2013

(54) SEMICONDUCTOR DEVICE MEASURING VOLTAGE APPLIED TO SEMICONDUCTOR SWITCH ELEMENT

(71) Applicant: Masayuki Kora, Fukuoka-shi (JP)

(72) Inventor: Masayuki Kora, Fukuoka-shi (JP)

(73) Assignee: Mitsubishi Electric Corporation, Chiyoda-ku (JP)

(21) Appl. No.: 13/541,154

(22) Filed: Jul. 3, 2012

(30) Foreign Application Priority Data
Nov. 15, 2011 (JP) 2011-249685

(51) Int. Cl. H03K 17/06

(52) U.S. Cl. 327/109

(57) ABSTRACT

A semiconductor device includes a semiconductor switch element including a first conduction electrode and a second conduction electrode, and a voltage measurement circuit for measuring voltage across the first conduction electrode and second conduction electrode of the semiconductor switch element. The voltage measurement circuit includes a diode element connected parallel to the semiconductor switch element to restrict the voltage applied in the conducting direction of the semiconductor switch element to a predetermined value, a control switch connected in series with the diode element, and a switch control unit setting the control switch at an OFF state when the semiconductor switch element is at an OFF state, and setting the control switch at an ON state when the semiconductor switch element is at an ON state.

### BACKGROUND OF THE INVENTION

1. Field of the Invention

The present invention relates to semiconductor devices, particularly a semiconductor device that measures voltage applied to a semiconductor switch element.

2. Description of the Background Art

In a semiconductor switching device employed in an inverter or the like for controlling the motor rotational speed as well as for an AC power supply device, detection of a semiconductor switch element being in an overcurrent state is made by, for example, measuring the ON voltage when current is conducted through the relevant semiconductor switch element.

Protection against overcurrent at an intelligent power module (IPM) incorporated in a driving circuit employed in an inverter or the like is conducted as set forth below. A current sense amplifier is provided for an insulated gate bipolar transistor (IGBT) chip. The current sense amplifier and a resistor are connected to monitor the voltage across the resistor. When a voltage exceeding a predetermined level is generated at the resistor, a gate signal to the IGBT chip is interrupted based on the assumption that overcurrent is generated at the IGBT chip, and an error signal is output.

As a configuration including a semiconductor switch element and measuring the voltage applied to the semiconductor switch element, Japanese Patent Laying-Open No. 2010-200411, for example, discloses a semiconductor device set forth below. The semiconductor device disclosed in the aforementioned publication includes a voltage measurement circuit for measuring the voltage across the drain and source of a semiconductor switch element. The voltage measurement circuit includes a Zener diode connected parallel to the semiconductor switch element to restrict the voltage applied in the conducting direction of the semiconductor switch element to a predetermined value, a control switch connected parallel to the Zener diode, and a switch control unit for controlling the ON/OFF of the control switch. The switch control unit functions to set the control switch ON when the semiconductor switch element is OFF, and the control switch OFF when the semiconductor switch element is ON.

Japanese Patent Laying-Open No. 2006-136086 discloses a configuration set forth below. A series circuit of a first resistor and a second resistor is connected across the source and drain of an MOSFET (Metal Oxide Semiconductor Field Effect Transistor) that is the subject of current detection. The ON voltage of the MOSFET is divided by a voltage division circuit including a first resistor and a second resistor to be applied to a detection circuit. The value is calculated to be converted into a current value to detect the current flowing to the MOSFET. According to this configuration, the voltage division ratio of the voltage division circuit including a first resistor and a second resistor varies according to the temperature. The voltage division ratio becomes larger as a function of higher temperature.

In the semiconductor device disclosed in Japanese Patent Laying-Open No. 2010-200411, the control switch is set at an ON state when the semiconductor switch element is at an OFF state. Therefore, current (I=V/R) flows to the path of the control switch. Accordingly, when the power supply voltage is increased at the semiconductor device disclosed in Japanese Patent Laying-Open No. 2010-200411, a great amount of current will flow to the control switch path, leading to greater current loss during an OFF state of the semiconductor switch element.

The semiconductor device disclosed in Japanese Patent Laying-Open No. 2010-200411 exhibits greater loss of the resistor element (V²/R) employed in the voltage measurement circuit when the current flowing through the path of the control switch increases. Therefore, a resistor element having a larger resistance will be required.

With regard to the semiconductor device disclosed in Japanese Patent Laying-Open No. 2006-136086, only the method of accurately detecting the ON voltage in a normal operation is disclosed. The publication is completely silent about the measurement method in an erroneous state such as in the event of short-circuiting (an active operation in which current flows and voltage is applied the element) and about measures against an error operation. There was the possibility that the detection circuit would be damaged by an erroneous operation.

### SUMMARY OF THE INVENTION

The present invention provides a semiconductor device suppressing current loss at a voltage measurement circuit, and avoiding damage of the voltage measurement circuit even in an erroneous operation.

According to an aspect of the present invention, a semiconductor device includes a semiconductor switch element having a first conduction electrode and a second conduction electrode, and a voltage measurement circuit for measuring voltage across the first conduction electrode and second conduction electrode of the semiconductor switch element. The voltage measurement circuit includes a constant voltage element, a control switch, and a switch control unit. The constant voltage element is connected parallel to the semiconductor switch element to restrict the voltage applied in the conducting direction of the semiconductor switch element to a predetermined value. The control switch is connected in series with the constant voltage element. The switch control unit sets the control switch at an OFF state when the semiconductor switch element is at an OFF state, and sets the control switch at an ON state when the semiconductor switch element is at an ON state.

According to the semiconductor device of the present invention, current will not flow to the voltage measurement circuit by setting the control switch at an OFF state when the semiconductor switch element is at an OFF state, allowing current loss to be suppressed. Since the semiconductor device of the present invention can restrict the voltage applied in the conducting direction of the semiconductor switch element by the constant voltage element even in the case of an erroneous operation, high voltage will not be applied to the semiconductor switch element and voltage measurement circuit. The safety of the circuitry is ensured.

The foregoing and other objects, features, aspects and advantages of the present invention will become apparent from the detailed description of the invention when considered in connection with the accompanying drawings.

### BRIEF DESCRIPTION OF THE DRAWINGS

FIG. 1 is a schematic diagram of a configuration of a semiconductor device according to a first embodiment of the present invention.

FIG. 2 is a timing chart representing an operation of the semiconductor device according to the first embodiment of the present invention detecting ON voltage of a semiconductor switch element.

FIG. 3 represents a configuration of a semiconductor device according to a second embodiment of the present invention.

FIG. 4 represents a configuration of a semiconductor device according to a third embodiment of the present invention.

FIG. 5 represents another configuration of a semiconductor device according to the third embodiment of the present invention.

FIG. 6 is a timing chart representing an operation of the semiconductor device according to a fourth embodiment of the present invention detecting ON voltage of a semiconductor switch element.

FIGS. 7, 8 and 9 represents a configuration of a semiconductor device according to a fifth embodiment, sixth embodiment, and seventh embodiment, respectively, of the present invention.

FIG. 10 represents another configuration of a semiconductor device according to the seventh embodiment of the present invention.

FIG. 11 represents a circuit diagram of a configuration of a general inverter device.

### DESCRIPTION OF THE PREFERRED EMBODIMENTS

Embodiments of the present invention will be described hereinafter with reference to the drawings.

### First Embodiment

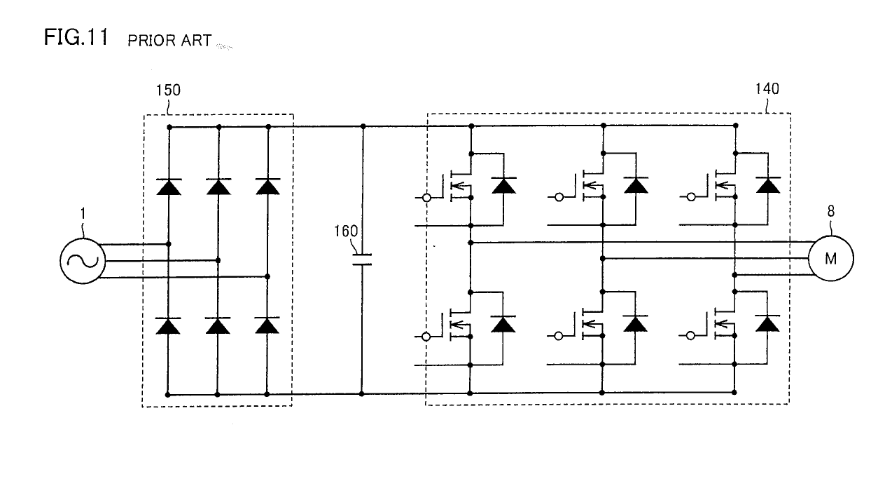

A semiconductor device according to the present invention can be applied to a general inverter device. FIG. 11 is a circuit diagram of a configuration of a general inverter. The inverter device of FIG. 11 includes a converter unit 150 connected to an AC power supply 1 for converting AC power into DC power, a smoothing capacitor 160 smoothing the DC power output from converter unit 150, and an inverter unit 140 controlling a plurality of semiconductor switch elements to drive a motor 8 based on the DC power smoothed at smoothing capacitor 160.

Particularly, the semiconductor device of the present invention is applied to inverter unit 140. For the sake of simplification, the following description is based on a configuration applied to one semiconductor switch element of inverter unit 140.

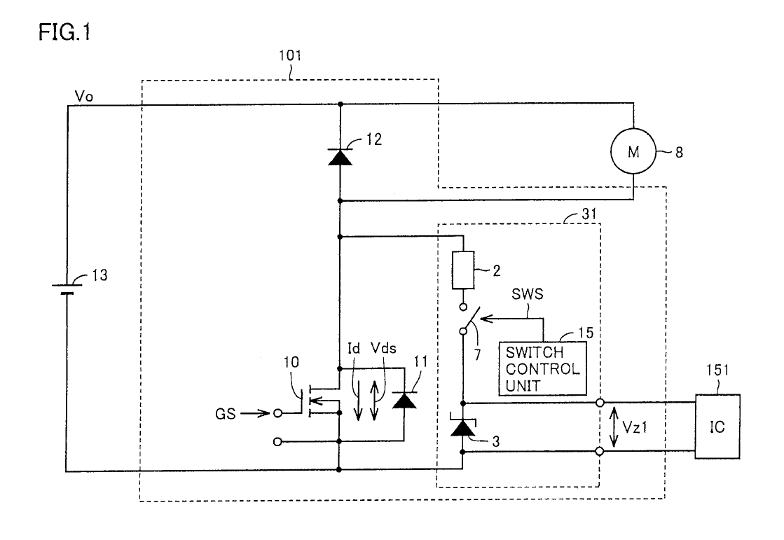

FIG. 1 is a schematic diagram representing a configuration of a semiconductor device according to a first embodiment of the present invention. A semiconductor device 101 of FIG. 1 includes a semiconductor switch element 10, a diode element 11, a clamp diode 12, and a voltage measurement circuit 31. Voltage measurement circuit 31 includes a resistor 2, a Zener diode 3, a control switch 7, and a switch control unit 15.

Semiconductor device 101 drives motor 8 based on DC power supplied from a power supply 13. Voltage measurement circuit 31 measures voltage Vz1 applied across Zener diode 3 to measure the voltage across the drain and source of semiconductor switch element 10. An IC 151 detects an overcurrent state of semiconductor switch element 10 based on the measured result of voltage measurement circuit 31.

Semiconductor switch element 10 is, for example, an MOSFET (Metal Oxide Semiconductor Field Effect Transistor) chip. The conducting direction of diode element 11 is opposite to the conducting direction of semiconductor switch element 10. Diode element 11 is, for example, a parasitic diode located between the drain and source of semiconductor switch element 10. Diode element 11 is employed as a free wheel diode.

Semiconductor switch element 10 includes a drain connected to an anode of clamp diode 12 and the first end of resistor 2, a source connected to the minus side terminal of power supply 13 and an anode of Zener diode 3, and a gate receiving a driving signal GS. Clamp diode 12 includes a cathode connected to the plus side terminal of power supply 13 and the first end of motor 8, and an anode connected to the second end of motor 8.

Semiconductor switch element 10 and the series circuit of resistor 2, control switch 7 and Zener diode 3 are connected parallel to each other. Zener diode 3 is connected such that its conducting direction is opposite to the conducting direction of semiconductor switch element 10. Zener diode 3 includes a cathode connected to the second end of control switch 7, and an anode connected to the source of semiconductor switch element 10. Control switch 7 includes a first end connected to the second end of resistor 2, and a second end connected to the cathode of Zener diode 3.

Resistor 2 is provided for the purpose of restricting the current flowing through Zener diode 3. Resistor 2 has its resistance value set such that sufficient voltage is applied to Zener diode 3. IC 151 is connected to the cathode and anode of Zener diode 3.

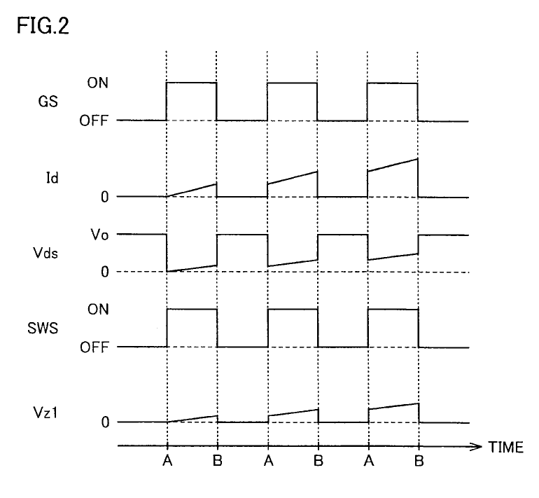

FIG. 2 is a timing chart representing an operation of semiconductor device 101 according to the first embodiment of the present invention detecting ON voltage of semiconductor switch element 10.

Referring to FIG. 2, GS represents the driving signal towards semiconductor switch element 10, i.e. the gate voltage of semiconductor switch element 10. Id represents the drain current of semiconductor switch element 10. Vds represents the drain-source voltage of semiconductor switch element 10. SWS represents a control signal to control switch 7. Vz1 represents the voltage across Zener diode 3.

Driving signal GS attains a logical high level during the period from timing A to timing B. Semiconductor switch element 10 is at an ON state during this period. Driving signal GS attains a logical low level during the period from timing B to timing A. Semiconductor switch element 10 is at an OFF state during this period.

Control signal SWS has a logical level identical to that of driving signal GS. Specifically, control signal SWS attains a logical high level during the period from timing A to timing B, and a logical low level during the period from timing B to timing A.

Let us now suppose that semiconductor device 101 does not include control switch 7 and Zener diode 3. In such a configuration, output voltage Vo of power supply 13 is applied across the drain and source of semiconductor switch element 10 when semiconductor switch element 10 is at an OFF state. Therefore, most of output voltage Vo is similarly applied to voltage measurement circuit 31 connected parallel to semiconductor switch element 10. This means that an IC 151 having a breakdown voltage greater than output voltage Vo will be required.

Semiconductor device 101 of the present invention includes a control switch 7 that is set at an OFF state by switch control unit 15 when semiconductor switch element 10 is OFF. Accordingly, the voltage applied to voltage measurement circuit 31 is applied to control switch 7. Voltage Vz1 across Zener diode 3 can be set at 0V.

Therefore, an IC 151 having a breakdown voltage greater than output voltage Vo will not be required. Furthermore, an erroneous determination of semiconductor switch element 10 in an overcurrent state by the detection of high voltage at IC 151 when semiconductor switch element 10 is at an OFF state can be prevented. Moreover, control to avoid a determination of an overcurrent state when semiconductor switch element 10 is at an OFF state no longer has to be carried out at IC 151, allowing simplification in control. Additionally, when semiconductor switch element 10 is OFF, current does not flow to voltage measurement circuit 31 since control switch 7 is OFF. Therefore, current loss can be suppressed.

Switch control unit 15 renders control switch 7 ON when semiconductor switch element 10 attains an ON state. For example, switch control unit 15 causes control switch 7 to attain an ON state from an OFF state simultaneous to the transition of semiconductor switch element 10 from an OFF state to an ON state. Accordingly, the ON voltage of the current flowing to semiconductor switch element 10 can be detected as voltage Vz1 across Zener diode 3 by IC 151 connected to voltage measurement circuit 31.

By the control through control switch 7 set forth above, voltage Vz1 having a voltage waveform changing likewise with drain current Ids, as shown in FIG. 2, is applied across Zener diode 3, which can be measured. Specifically, voltage Vz1 can be detected as the ON voltage of semiconductor switch element 10. By detecting the ON voltage of semiconductor switch element 10, the current flowing through semiconductor switch element 10 can be measured, allowing detection of an overcurrent state of semiconductor switch element 10.

Let us now suppose that semiconductor device 101 does not include Zener diode 3. In such a configuration, when motor 8 is faulty and an erroneous operation such as short-circuiting occurs, output voltage Vo will be applied across each of semiconductor switch element 10 and voltage measurement circuit 31 since control switch 7 is at an ON state when semiconductor switch element 10 is at an ON state.

However, by virtue of semiconductor device 101 having Zener diode 3 according to the present invention, the voltage applied across semiconductor switch element 10 and voltage measurement circuit 31 will not exceed the Zener voltage of Zener diode 3 even in the case where motor 8 is faulty and an erroneous operation such as short-circuiting occurs. Thus, the breakdown voltage of the elements constituting semiconductor switch element 10 and voltage measurement circuit 31 can be reduced at a low level.

Since voltage Vz1 will not exceed the Zener voltage of Zener diode 3 in semiconductor device 101, IC 151 for measuring voltage Vz1 does not require a high breakdown voltage. Therefore, IC 151 can be designed readily, allowing reduction in the size and cost.

Further, a switch of small capacitance can be employed for control switch 7 since the current flow is restricted by resistor 2. Therefore, the size and cost can be reduced.

Semiconductor device 101 according to the first embodiment of the present invention can measure accurately the voltage applied to semiconductor switch element 10 with a simple configuration. Since an overcurrent state of a semiconductor switch element can be detected properly, the yield can be improved.

Although semiconductor device 101 according to the first embodiment of the present invention was described with semiconductor switch element 10 as a MOSFET chip, the present invention is not limited thereto. Another type of semiconductor switch element 10 such as an insulated gate bipolar transistor (IGBT) may be employed.

Semiconductor device 101 according to the first embodiment of the present invention is based on, but not limited to a configuration including Zener diode 3. Any constant voltage element connected parallel to semiconductor switch element 10, and restricting the voltage applied in the conducting direction of semiconductor switch element 10 to a predetermined value may be employed. Such a constant voltage element includes a varistor, for example.

Semiconductor device 101 according to the first embodiment of the present invention is based on, but not limited to a configuration in which the parasitic diode of semiconductor switch element 10 is employed as a free wheel diode. A configuration in which a Schottky barrier diode (SBD) having a small forward voltage is provided as a free wheel diode may be implemented to reduce current consumption in a regeneration mode of motor 8 in the case where an IGBT without a parasitic diode is employed as semiconductor switch element 10, or when an MOSFET is employed as semiconductor switch element 10.

### Second Embodiment

The second embodiment relates to a semiconductor device having the constant voltage element modified as compared to the semiconductor device of the first embodiment. The contents other than those that will be described hereinafter are similar to those of the semiconductor device of the first embodiment. The same or corresponding elements in the drawings have the same reference characters allotted, and description thereof will not be repeated.

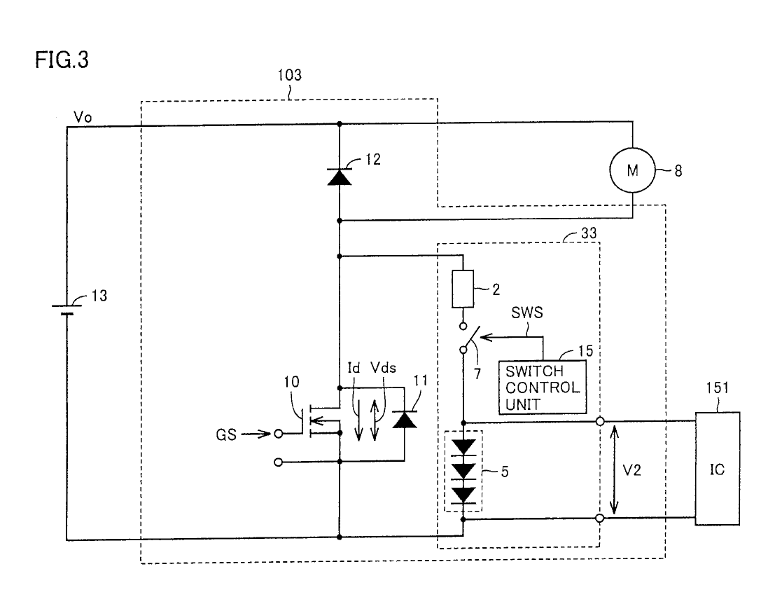

FIG. 3 represents a configuration of a semiconductor device according to a second embodiment of the present invention.

Referring to FIG. 3, a semiconductor device 103 differs from semiconductor device 101 of the first embodiment by including a voltage measurement circuit 33 instead of voltage measurement circuit 31. Voltage measurement circuit 33 includes a resistor 2, a diode unit 5, a control switch 7, and a switch control unit 15.

Diode unit 5 is connected in series with resistor 2 and control switch 7. Semiconductor switch element 10 and the series circuit of resistor 2, control switch 7 and diode unit 5 are connected parallel to each other. Diode unit 5 includes a plurality of diodes connected in series such that the conducting direction is identical to the conducting direction of semiconductor switch element 10. Diode unit 5 restricts the voltage applied in the conducting direction of semiconductor switch element 10 to a predetermined value.

Voltage measurement circuit 33 measures the voltage across the drain and source of semiconductor switch element 10 by measuring voltage V2 applied across diode unit 5.

The semiconductor device according to the second embodiment of the present invention can adjust the maximum level of voltage V2 by modifying the number of diodes at diode unit 5.

The remaining configuration and operation are similar to those of semiconductor device 101 of the first embodiment. Therefore, detailed description thereof will not be repeated.

Semiconductor device 103 according to the second embodiment of the present invention is based on, but not limited to a configuration including diode unit 5, and a semiconductor element conducting bidirectionally such as a varistor may be employed.

Such a configuration can provide effects similar to those of the semiconductor device according to the second embodiment of the present invention.

### Third Embodiment

A third embodiment relates to a semiconductor device having an adjustment function of voltage Vz1 across Zener diode 3 added, as compared with semiconductor device 101 of the first embodiment. The contents other than those that will be described hereinafter are similar to those of the semiconductor device of the first embodiment. The same or corresponding elements in the drawings have the same reference characters allotted, and description thereof will not be repeated.

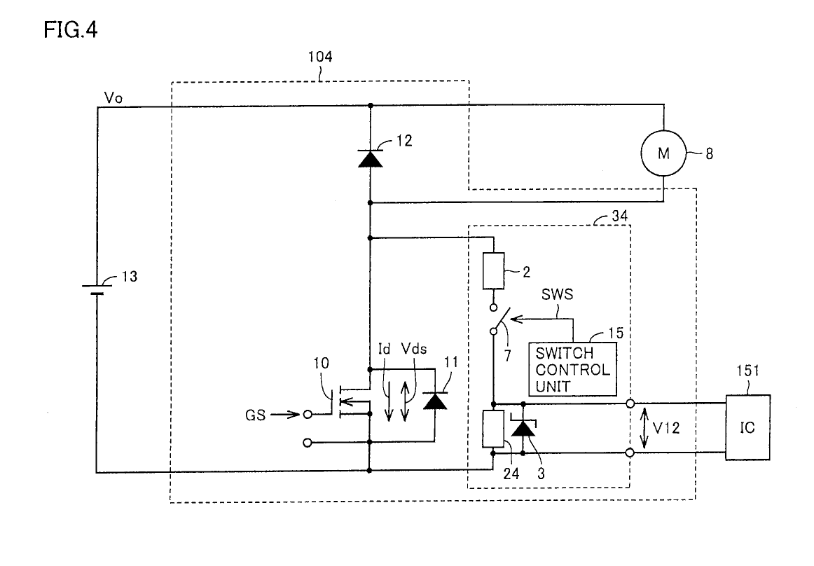

FIG. 4 represents a configuration of a semiconductor device according to a third embodiment of the present invention.

Referring to FIG. 4, a semiconductor device 104 differs from semiconductor device 101 of the first embodiment by including a voltage measurement circuit 34 instead of voltage measurement circuit 31. Voltage measurement circuit 34 includes a resistor 2, a Zener diode 3, a control switch 7, a switch control unit 15, and a resistor 24. Resistor 24 is connected in series with resistor 2 and control switch 7, and parallel to semiconductor switch element 10, diode element 11 and Zener diode 3.

Semiconductor device 101 according to the previous first embodiment has the drain-source voltage, i.e. the ON voltage, of semiconductor switch element 10 at an ON state applied across Zener diode 3.

Semiconductor device 104 according to the third embodiment can divide the ON voltage of semiconductor switch element 10 by resistor 2 and resistor 24. Therefore, the level of voltage V12 applied across Zener diode 3 can be adjusted.

The level of the voltage across Zener diode 3 can also be adjusted by replacing resistor 2 with a plurality of resistors connected in series, or by adjusting the resistance of resistor 2.

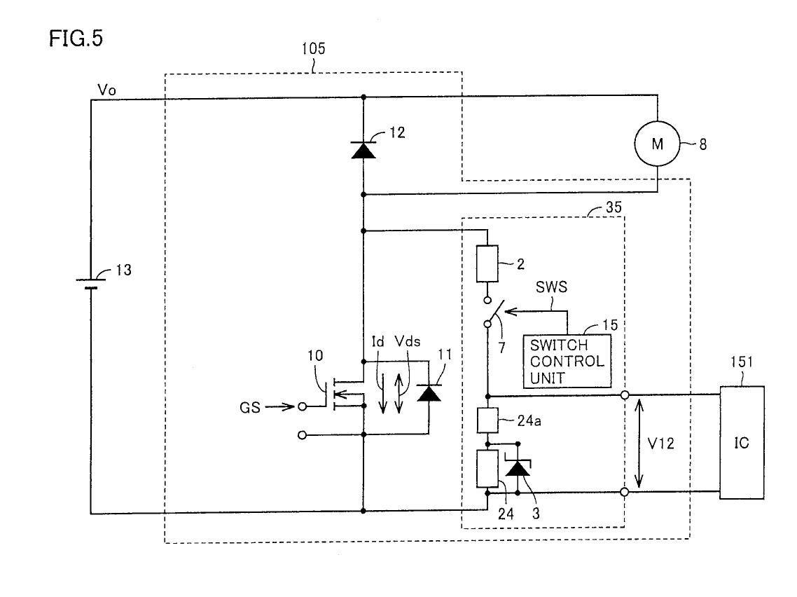

Resistor 24 is not limited to the case of being connected parallel to Zener diode 3, and may be connected in series with Zener diode 3. FIG. 5 represents another configuration of a semiconductor device according to the third embodiment of the present invention. A semiconductor device 105 of FIG. 5 differs from semiconductor device 104 of FIG. 4 by including a voltage measurement circuit 35 instead of voltage measurement circuit 34. Voltage measurement circuit 35 includes a resistor 2, a Zener diode 3, a control switch 7, a switch control unit 15, and resistors 24 and 24a. Resistor 24a is connected in series with Zener diode 3, between the terminals connected to IC 151. Semiconductor device 105 of FIG. 5 can divide the ON voltage of semiconductor switch element 10 by resistor 2 and resistors 24, 24a. Therefore, the level of voltage V12 applied across Zener diode 3 can be adjusted.

The remaining configuration and operation are similar to those of semiconductor device 101 of the first embodiment. Therefore, detailed description thereof will not be repeated.

### Fourth Embodiment

The fourth embodiment relates to a semiconductor device having the control contents of switch control unit 15 modified as compared to semiconductor device 101 of the first embodiment. The contents other than those that will be described hereinafter are similar to those of semiconductor device 101 of the first embodiment.

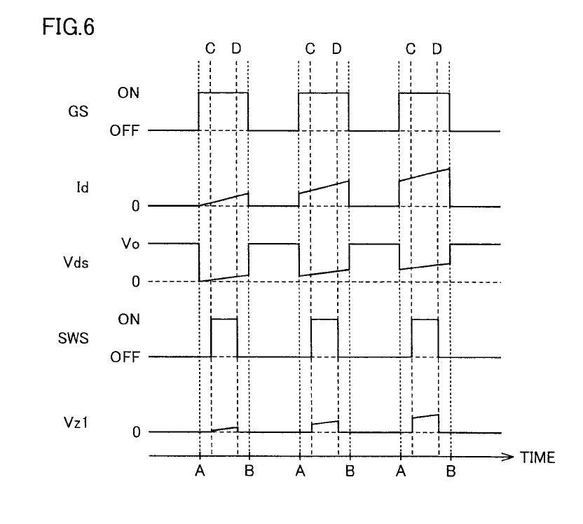

FIG. 6 is a timing chart representing an operation of the semiconductor device according to the fifth embodiment of the present invention detecting ON voltage of a semiconductor switch element.

Referring to FIG. 6, switch control unit 15 maintains control switch 7 at an OFF state until an elapse of a predetermined time from turning semiconductor switch element 10 to an ON state, then turns control switch 7 ON at an elapse of a predetermined time, and then turns control switch 7 OFF prior to an elapse of a predetermined time from semiconductor switch element 10 turned OFF.

Specifically, control signal SWS takes a logical high level during the period from timing A to timing B. Control switch 7 is ON during this period. Further, control signal SWS remains at a logical low level until an elapse of a predetermined time from timing A to timing C. During this period, control switch 7 maintains an OFF state. Then, control signal SWS attains a logical high level during the period from timing C to timing D, and turns control switch 7 OFF at timing D prior to an elapse of a predetermined time from timing B where semiconductor switch element 10 is turned OFF.

By such a configuration, a sudden change in the level of voltage Vz1 caused by noise or the like generated at the time of transition from an OFF state to an ON state, or from an ON state to an OFF state of semiconductor switch element 10 can be suppressed. Thus, an erroneous operation of detecting overcurrent can be prevented.

The remaining configuration and operation are similar to those of semiconductor device 101 of the first embodiment. Therefore, detailed description thereof will not be repeated.

During the period of measuring the voltage across the drain and source of semiconductor switch element 10 at voltage measurement circuit 31 (the period from timing C to timing D), switch control unit 15 according to the fourth embodiment does not have to bring at least one of the measurement start timing (timing C) or the measurement end timing (timing D) in synchronization with the switching period of semiconductor switch element 10.

### Fifth Embodiment

The fifth embodiment relates to a semiconductor device having a function for stabilizing voltage Vz1 across Zener diode 3 added, as compared to semiconductor device 101 of the first embodiment. The contents other than those that will be described hereinafter are similar to those of semiconductor device 101 of the first embodiment. The same or corresponding elements in the drawings have the same reference characters allotted, and description thereof will not be repeated.

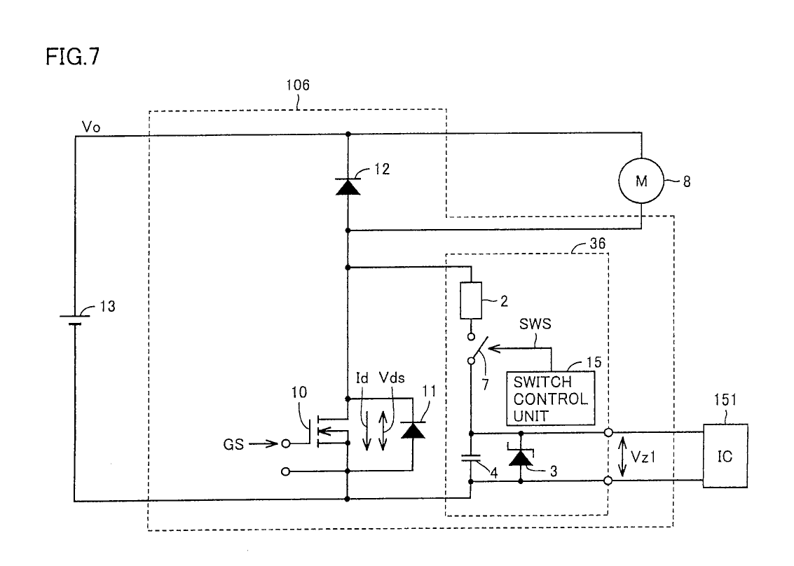

FIG. 7 represents a configuration of semiconductor device according to a fifth embodiment of the present invention.

Referring to FIG. 7, a semiconductor device 106 differs from semiconductor device 101 according to the first embodiment of the present invention by including a voltage measurement circuit 36 instead of voltage measurement circuit 31. Voltage measurement circuit 36 includes a resistor 2, a Zener diode 3, control switch 7, a switch control unit 15, and a capacitor 4. Capacitor 4 is connected in series with resistor 2 and switch control unit 15, and parallel to semiconductor switch element 10, diode element 11, and Zener diode 3.

At semiconductor device 106, a sudden change in the level of voltage Vz1 caused by noise and ringing generated at the time of transition between an ON state and an OFF state of semiconductor switch element 10 can be suppressed by capacitor 4. Accordingly, an erroneous operation of detecting overcurrent can be prevented.

The remaining configuration and operation are similar to those of semiconductor device 101 of the first embodiment. Therefore, detailed description thereof will not be repeated.

### Sixth Embodiment

The sixth embodiment is related to a semiconductor device having semiconductor device 101 of the first embodiment set as a module. The contents other than those that will be described hereinafter are similar to those of the semiconductor device of the first embodiment.

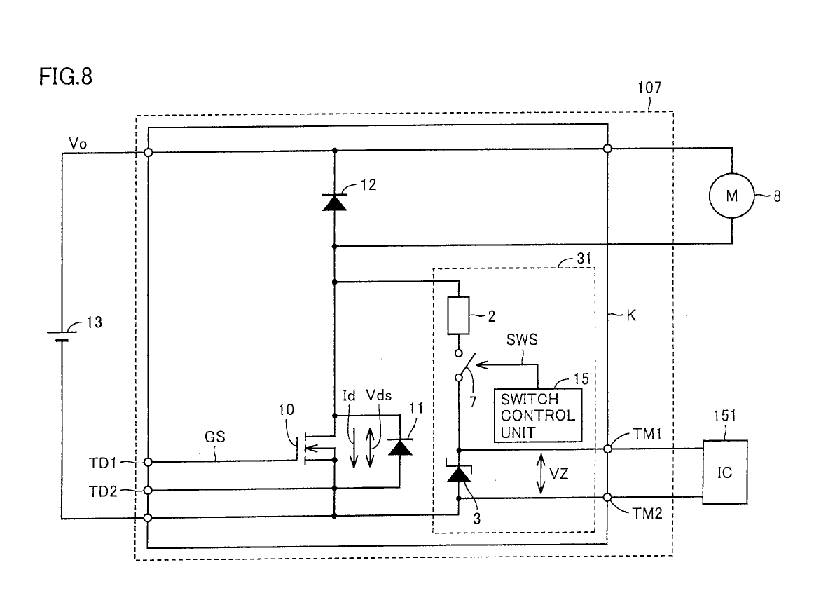

FIG. 8 represents a configuration of a semiconductor device according to a sixth embodiment of the present invention.

Referring to FIG. 8, a semiconductor device 107 further includes a case K, drive terminals TD1 and TD2, and monitor terminals TM1 and TM2, as compared to semiconductor device 101 according to the first embodiment of the present invention.

Case K stores semiconductor switch element 10, diode element 11, clamp diode 12, and voltage measurement circuit 31. Drive terminals TD1 and TD2 and monitor terminals TM1 and TM2 are attached to case K.

A driving signal GS is applied from outside case K to the gate of semiconductor switch element 10 via drive terminal TD1. Voltage Vz1 applied across Zener diode 3 is applied to IC 151 located outside case K via monitor terminals TM1 and TM2.

By such a configuration, the ON voltage of semiconductor switch element 10 can be readily measured from outside of semiconductor device 101.

The remaining configuration and operation are similar to those of semiconductor device 101 of the first embodiment. Therefore, detailed description thereof will not be repeated.

### Seventh Embodiment

The seventh embodiment relates to a semiconductor device having semiconductor device 101 according to the first embodiment set as an intelligent power module (IPM). The contents other than those that will be described hereinafter are similar to those of semiconductor device 101 of the first embodiment. The same or corresponding elements in the drawings have the same reference characters allotted, and description thereof will not be repeated.

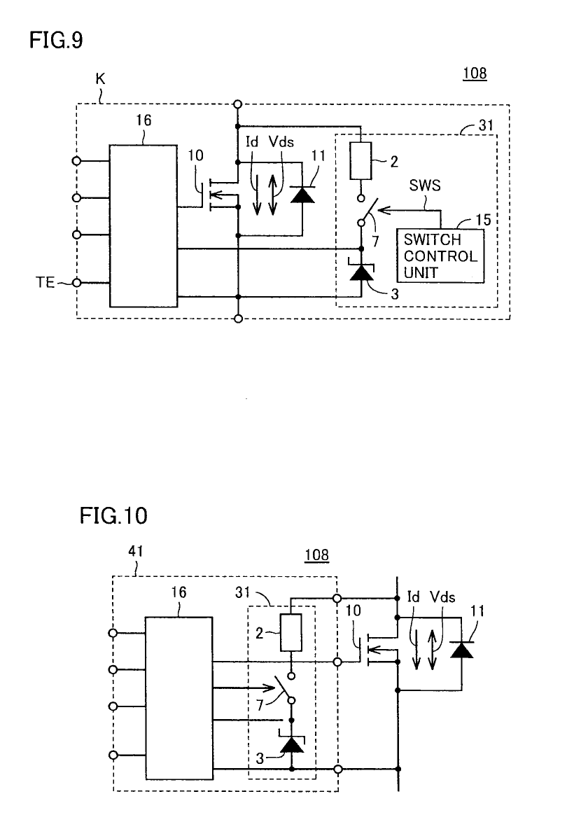

FIG. 9 represents a configuration of a semiconductor device according to the seventh embodiment of the present invention.

Referring to FIG. 9, a semiconductor device 108 further includes a case K, an error terminal TE, and a driving unit 16, as compared to semiconductor device 101 according to the first embodiment of the present invention.

Case K stores semiconductor switch element 10, diode element 11, voltage measurement circuit 31, and driving unit 16. Error terminal TE is attached to case K.

Driving unit 16 outputs a driving signal GS for driving semiconductor switch element 10 to the gate thereof. Based on the measured result of voltage measurement circuit 31, i.e. the level of voltage Vz1 applied across Zener diode 3, driving unit 16 includes overcurrent detection means for control to stop the output of driving signal GS to semiconductor switch element 10 and to turn semiconductor switch element 10 OFF through driving unit 16. Further, based on the measured result at voltage measurement circuit 31, driving unit 16 can output an error signal indicating that semiconductor switch element 10 is in an overcurrent state to an external source of case 7 via error terminal TE.

By virtue of incorporating driving unit 16 having an interrupting function of driving signal GS inside the module of semiconductor device 108, the response speed to overcurrent can be facilitated. Therefore, damage to semiconductor switch element 10 can be obviated. Furthermore, since the length of the wiring for transmitting voltage Vz1 can be shortened, voltage Vz1 transmitted to driving unit 16 is less likely to be affected by noise and the like, allowing an erroneous operation of detecting overcurrent to be prevented.

At semiconductor device 108, voltage measurement circuit 31 and driving unit 16 may be set as one integrated circuit, i.e. one semiconductor chip. FIG. 10 represents another configuration of semiconductor device 108 according to the seventh embodiment of the present invention. Semiconductor device 108 of FIG. 10 has voltage measurement circuit 31 and driving unit 16 configured by one semiconductor chip 41. Accordingly, semiconductor device 108 of FIG. 10 can realize, as an overall module, reduction of the size and cost as well as improvement in assembly.

The remaining configuration and operation are similar to those of semiconductor device 101 of the first embodiment. Therefore, detailed description thereof will not be repeated.

### Eighth Embodiment

The eighth embodiment relates to a semiconductor device having the type of semiconductor switch element 10 modified, as compared to semiconductor device 101 of the first embodiment. The contents other than those that will be described hereinafter are similar to those of the semiconductor device of the first embodiment. The same or corresponding elements in the drawings have the same reference characters allotted, and description thereof will not be repeated.

The semiconductor device of the eighth embodiment has a configuration similar to that of semiconductor device 101 of FIG. 1, and differs therefrom in that semiconductor switch element 10 and diode element 11 are formed of silicon carbide (SiC).

By virtue of silicon carbide having a high breakdown voltage and allowing a larger Permissible current density, semiconductor switch element 10 and diode element 11 can be reduced in size. Therefore, the semiconductor device according to the eighth embodiment of the present invention can be further reduced in size as compared to semiconductor device 101 according to the first embodiment.

The semiconductor device according to the eighth embodiment of the present invention is based on, but not limited to a configuration in which semiconductor switch element 10 and diode element 11 are formed of silicon carbide (SiC). A configuration may be employed in which at least one of semiconductor switch element 10 and diode element 11 is formed of silicon carbide (SiC).

The remaining configuration and operation are similar to those of the semiconductor device of the first embodiment. Therefore, detailed description thereof will not be repeated.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a semiconductor switch element including a first conduction electrode and a second conduction electrode, and
a voltage measurement circuit for measuring voltage across said first conduction electrode and said second conduction electrode of said semiconductor switch element,
said voltage measurement circuit including
a constant voltage element connected parallel to said semiconductor switch element to restrict voltage applied in a conducting direction of said semiconductor switch element to a predetermined value,
a control switch connected in series with said constant voltage element, and
a switch control unit setting said control switch at an OFF state when said semiconductor switch element is at an OFF state, and setting said control switch at an ON state when said semiconductor switch element is at an ON state.

2. The semiconductor device according to claim 1, wherein
said constant voltage element is a Zener diode,
said voltage measurement circuit further including a first resistor element connected in series with said constant voltage element and said control switch.

3. The semiconductor device according to claim 1, wherein
said constant voltage element is a plurality of diodes connected in series,
said voltage measurement circuit further including a first resistor element connected in series with said constant voltage element and said control switch.

4. The semiconductor device according to claim 1, wherein said voltage measurement circuit further includes a second resistor element connected parallel to said semiconductor switch element and said constant voltage element.

5. The semiconductor device according to claim 1, wherein said voltage measurement circuit further includes a capacitor connected parallel to said semiconductor switch element and said constant voltage element.

6. The semiconductor device according to claim 1, wherein said switch control unit sets said control switch at an OFF state for a predetermined time among a period of an ON state of said semiconductor switch element.

7. The semiconductor device according to claim 1, further comprising:
a case storing said semiconductor switch element, said constant voltage element, and said control switch, and
a terminal attached to said case for measuring voltage applied to said constant voltage element.

8. The semiconductor device according to claim 1, further comprising:
a driving unit to output a driving signal for driving said semiconductor switch element to said semiconductor switch element, and
a case storing said semiconductor switch element, said voltage measurement circuit, and said driving unit,
wherein said driving unit stops output of said driving signal to said semiconductor switch element, based on a level of voltage applied to said constant voltage element, and outputs an error signal indicating an overcurrent state of said semiconductor switch element.

9. The semiconductor device according to claim 8, wherein said voltage measurement circuit and said driving unit are included in one semiconductor integrated circuit.

10. The semiconductor device according to claim 8, wherein said semiconductor switch element is formed of silicon carbide.
